(19) United States
(12) Patent Application Publication
(10) Pub. No.: US 2014/0145328 A1
(43) Pub. Date: May 29, 2014

(54) INTERCONNECT ASSEMBLIES AND METHODS OF MAKING AND USING SAME

(71) Applicant: Georgia Tech Research Corporation, Atlanta, GA (US)

(72) Inventors: Rao Tummala, Greensboro, GA (US); Venkatesh Sundaram, Alpharetta, GA (US); Markondeya Raj Pulugurtha, Tucker, GA (US); Tao Wang, Atlanta, GA (US); Vanessa Smet, Atlanta, GA (US)

(73) Assignee: Georgia Tech Research Corporation, Atlanta, GA (US)

(21) Appl. No.: 14/160,136

(22) Filed: Jan. 21, 2014

Related U.S. Application Data
(63) Continuation-in-part of application No. 13/383,727, filed on Jan. 12, 2012, now Pat. No. 8,633,601.
(60) Provisional application No. 61/225,015, filed on Jul. 13, 2009.
(60) Provisional application No. 61/307,113, filed on Feb. 23, 2010.

(51) Int. Cl. H01L 23/00

(52) U.S. Cl. CPC H01L 24/05; H01L 24/03; H01L 24/13; H01L 24/11
USPC 257/737; 438/613

(57) ABSTRACT

The various embodiments of the present invention provide fine pitch, chip-to-substrate hybrid interconnect assemblies, as well as methods of making and using the assemblies. The hybrid assemblies generally include a semiconductor having a die pad disposed thereon, a substrate having a substrate pad disposed thereon, and a polymer layer disposed between the surface of the die pad and the surface of the substrate pad. In addition, at least a portion of the surface of the die pad is metallically bonded to at least a portion of the surface of the substrate pad and at least a portion of the surface of the die pad is chemically bonded to at least a portion of the surface of the substrate pad.

### CROSS-REFERENCE TO RELATED APPLICATIONS

This application is a continuation-in-part application claiming priority under 35 U.S.C. §120 to U.S. patent application Ser. No. 13/383,727, filed 12 Jan. 2012, which claimed the benefit of International Patent Application Serial Number PCT/US2010/041828, filed 13 Jul. 2010, which claimed the benefit of U.S. Provisional Patent Application Ser. No. 61/225,015, filed 13 Jul. 2009, and U.S. Provisional Patent Application Ser. No. 61/307,113, filed 23 Feb. 2010, all of which are hereby incorporated by reference in their entirety as if fully set forth below.

### TECHNICAL FIELD

The various embodiments of the present invention relate generally to fine pitch, chip-to-substrate interconnects, wherein a bump interconnect is utilized, and to methods of making and using the same.

### BACKGROUND

In a continuous drive to achieve low form-factor packages, chip-to-substrate interconnect devices have evolved from conventional solder-based techniques. As microelectronic systems follow the trend toward higher functionality with ever-decreasing dimensions, the miniaturization of electrical systems has called for a much wider perspective, requiring active and passive devices to be integrated at both micro- and nano-scales. The “system on package” (SOP) concept for integration of logic, memory, RF and MEMS in 2D, 2.5D and 3D overcomes the limitations of single-chip integration (System on Chip—SOC) to enable electrical systems to be scaled, promised a paradigm shift in the way systems were perceived, and set a roadmap for ultra-miniaturization with novel interconnect solutions.

For example, one such interconnect solution involves chip-to-substrate interconnect assemblies that utilize “flip-chip” technology. In general, solder bumps were placed on an active surface of a chip, and the chip was subsequently flipped such that the solder bumps could be connected to a substrate pad. However, material, processing and physical constraints due to the geometry of the interconnection became an obstacle in reducing the bump pitch or density and achieving high reliability. In addition, electro-migration issues and intermetallic formations posed additional concerns. Several interconnect assemblies have been explored to achieve ultra-fine pitch, for example, pad-to-pad gold bonding and bump-to-pad nickel bonding. Pad-to-pad gold bonding cures the aforementioned defects of solder bumps; however, the bonding is relatively expensive to make. Further, low bonding temperature cannot be achieved with bump-to-pad nickel bonding. Therefore, there is a need in the art for a fine pitch, chip-to-substrate interconnect assembly that is compatible with flip-chip technology, less costly than gold interconnects, and has the ability to handle increased input/output (I/O) density.

The continuous need for higher bandwidth, high signal speed, lower power and higher I/O density for emerging mobile and high-performance systems is projected to drive off-chip interconnection pitch to 30 μm and below by 2016. The evolution of low-CTE (coefficient of thermal expansion) glass and silicon interposers with dimensional stability recently enabled lithographic dimensions of less than 3 μm and stress reduction with Cu-ultralow K dielectrics, which addresses the challenges of chip-package interactions at these dimensions. However, the lack of a manufacturable chip-to-chip interposer, chip-to-chip or chip-to-package interconnection technology at ultra-fine pitch is still a major bottleneck to accomplish this goal.

Cu pillars with solder caps have evolved over the past two decades for pitches down to 40 μm, relying on flux-function added NCFs (non-conductive adhesive films) or underfills to reduce the risk of solder bridging during bonding. Further pitch reduction with Cu-solder approaches is primarily hindered by fundamental material limitations such as current-carrying capability and electromigration resistance of solders, process barriers such as ultra-fine pitch bumping, control of solder volume and alloy composition, solder bridging, control of the intermetallic compounds (IMCs), coplanarity and warpage challenges, and the resulting electrical and thermo-mechanical reliability challenges.

Solder-free Cu interconnection technologies have been extensively researched as the most promising alternative to achieve ultra-fine pitch below 40 μm by solid-state bonding without the risk of interconnection-bridging from bump-collapse. Copper has very high electrical and thermal conductivities enabling high-speed signal transmission and high current carrying capability and is compatible with CMOS BEOL processes. Careful Cu surface preparation such as chemical-mechanical polishing (CMP) and removal of residual oxides, combined with high-temperature and longer annealing times for interdiffusion and recrystallization are generally required to achieve finer pitch. For example, current direct Cu—Cu bonding technologies require bonding temperatures as high as 350° C., which lowers the throughput and escalates the manufacturing cost.

Traditional Au—Au thermo-compression bonding is generally pursued at temperatures above 200° C. with higher Au thicknesses. Hybrid Au-underfill bonding has been demonstrated by thermocompression bonding at 250° C. but requires a specific lock-and-key structure to prevent void formation in the underfill.

### SUMMARY

Some embodiments of the present invention provide fine pitch, chip-to-chip interposer, chip-to-chip, and chip-to-substrate interconnect assemblies. Other embodiments provide methods of making fine pitch, chip-to-substrate interconnect assemblies. Finally, some embodiments provide methods of using fine pitch, chip-to-substrate interconnect assemblies.

According to some embodiments of the present invention, an interconnect assembly can include a semiconductor, an electrically conducting die pad disposed on at least a portion of a surface of the semiconductor, and an electrically conducting bump disposed on at least a portion of the die pad. In addition, the interconnect assembly can include a substrate and an electrically conducting substrate pad disposed on at least a portion of a surface of the substrate. The bump can be configured to electrically interconnect at least a portion of the semiconductor with at least a portion of the substrate when the bump is contacted with the substrate pad. Upon contacting the bump to the substrate pad, at least a portion of the bump and at least a portion of the substrate pad can substantially deform to create a non-metallurgical bond therebetween. In some cases, the non-metallurgical bond is a pressurized contact bond.

The interconnect assembly can further include a dielectric layer disposed between the substrate and the substrate pad. In such cases, it is possible for at least a portion of the dielectric layer to at least partially deform upon contacting the bump to the substrate pad.

The interconnect assembly can further comprise an intermediate bonding layer that is disposed between the bump and substrate pad.

The deformation of at least a portion of the bump and at least a portion of the substrate pad can be formed from an applied pressure of at least about 300 megaPascals.

The interconnect assembly can also include a non-reactive adhesive disposed between the bump and the substrate bad, wherein the non-reactive is configured to enhance the non-metallurgical bond. In some cases the adhesive can be formed from a non-conductive film. In other cases, the adhesive can be formed from an anisotropically conductive material.

In some cases, the die pad, bump, and/or substrate pad can be formed from copper. This allows interconnection between a semiconductor and an organic substrate, an inorganic substrate, or another semiconductor.

When two or more bumps are used, a distance between one bump and an adjacent bump can be less than or equal to about 30 micrometers. In some cases, the distance between every bump and an adjacent bump is less than or equal to about 30 micrometers.

According to some embodiments of the present invention, a method of making an interconnect assembly includes providing a semiconductor that comprises an electrically conducting die pad disposed on at least a portion of a surface of the semiconductor and an electrically conducting bump disposed on at least a portion of the die pad. The method can also include providing a substrate that comprises an electrically conducting substrate pad disposed on at least a portion of a surface of the substrate. Still further, the method can include contacting the electrically conducting bump with the electrically conducting substrate pad. The method can also include deforming at least a portion of the bump and at least a portion of the substrate pad to create a non-metallurgical bond therebetween.

It should be noted that the substrate pad can be disposed on a dielectric layer that serves as the surface of the substrate. In such cases, at least a portion of the dielectric layer can be deformed during the deforming step.

The deforming step can involve applying a pressure of at least about 300 megaPascals.

The method can further include disposing a non-reactive adhesive between the bump and the substrate pad such that non-reactive adhesive is configured to enhance the non-metallurgical bond. When two or more bumps are involved, a distance between one bump and an adjacent bump can be less than or equal to about 30 micrometers. In some cases, the distance between every bump and an adjacent bump is less than or equal to about 30 micrometers.

Another interconnect assembly, according to some embodiments of the present invention, can include a semiconductor, a copper die pad disposed on at least a portion of a surface of the semiconductor, and a copper bump disposed on at least a portion of the copper die pad. The interconnect assembly can also include a substrate and a copper substrate pad disposed on at least a portion of a surface of the substrate. The interconnect assembly can also include a non-reactive adhesive. Within the interconnect assembly, the copper bump can be configured to electrically interconnect at least a portion of the semiconductor with at least a portion of the substrate when the copper bump is contacted with the copper substrate pad. Upon contacting the copper bump to the copper substrate pad, at least a portion of the bump and at least a portion of the substrate pad can be substantially deformed to create a non-metallurgical bond therebetween. The non-metallurgical bond can be enhanced by the non-reactive adhesive.

An embodiment of the present invention can be a hybrid interconnect assembly, that can comprise a semiconductor and a die pad disposed on at least a portion of a surface of the semiconductor. The die pad can be formed from an electrically conducting material. The hybrid interconnect assembly can further comprise a substrate and a substrate pad disposed on at least a portion of a surface of the substrate. The substrate pad can be formed from an electrically conducting material. The hybrid interconnect assembly can further comprise a polymer layer disposed between a surface of the die pad and a surface of the substrate pad. In an embodiment, at least a portion of the surface of the die pad can be metallically bonded to at least a portion of the surface of the substrate pad and at least a portion of the surface of the die pad can be chemically bonded to at least a portion of the surface of the substrate pad.

An embodiment of the present invention can be a method of making a hybrid interconnect assembly. The method can comprise providing a semiconductor that can comprise an electrically conducting die pad disposed on at least a portion of a surface of the semiconductor. At least a portion of the die pad can have a non-planar surface. In an embodiment, the surface can comprise one or more defects. The method can further comprise providing a substrate that can comprise an electrically conducting substrate pad disposed on at least a portion of a surface of the substrate. At least a portion of the substrate pad can have a non-planar surface. In an embodiment, the surface can comprise one or more defects. The method can further comprise disposing a polymer layer on one or more of the surface of the semiconductor, the surface of the substrate, the surface of the substrate pad, and the surface of the die pad, positioning the surface of the die pad adjacent to the surface of the electrically conducting substrate pad and deforming at least a portion of the die pad and at least a portion of the substrate pad to form at least one of a chemical bond and a metallic bond therebewteen.

Other aspects and features of embodiments of the present invention will become apparent to those of ordinary skill in the art, upon reviewing the following description of specific, exemplary embodiments of the present invention in concert with the various figures. While features of the present invention may be discussed relative to certain embodiments and figures, all embodiments of the present invention can include one or more of the features discussed in this application. While one or more embodiments may be discussed as having certain advantageous features, one or more of such features may also be used with the other various embodiments of the invention discussed in this application. In similar fashion, while exemplary embodiments may be discussed below as system or method embodiments it is to be understood that such exemplary embodiments can be implemented in various devices, systems, and methods. Thus discussion of one feature with one embodiment does not limit other embodiments from possessing and including that same feature.

### BRIEF DESCRIPTION OF THE DRAWINGS

FIG. 1 is a schematic illustration of a semiconductor, a die pad, and a bump in accordance with some embodiments of the present invention.

FIG. 2 is a schematic illustration of a chip-to-substrate interconnect assembly in accordance with some embodiments of the present invention.

FIG. 3 is a scanning electron microscope (SEM) image of a chip-to-substrate interconnect assembly in accordance with some embodiments of the present invention.

FIG. 4 is a schematic illustration of a method of manufacturing the chip-to-substrate assembly in accordance with some embodiments of the present invention.

FIG. 5 is a schematic illustration of a cross-section of an interconnect assembly in accordance with some embodiments of the present invention.

FIG. 6 is a schematic illustration of a die (left) and substrate (right) design depicting Kelvin probe and daisy chain structures in accordance with some embodiments of the present invention.

FIG. 7 is a schematic illustration of a substrate design depicting daisy chain structures in accordance with some embodiments of the present invention.

FIG. 8 is an SEM image of a die and substrate in accordance with some embodiments of the present invention.

FIG. 9 is a schematic illustration of a die (left) and substrate (right) design depicting daisy chain and center array structures in accordance with some embodiments of the present invention.

FIG. 10 is a schematic illustration of a die and a substrate at different pitches in accordance with some embodiments of the present invention.

FIG. 11 is a SEM image of four substantially coplanar copper bumps in accordance with some embodiments of the present invention.

FIG. 12 is a graph that depicts the height of 38 randomly-measured bumps on a given die in accordance with some embodiments of the present invention.

FIG. 13 graphically depicts individual daisy chain resistance values during a thermal cycling test of interconnect assemblies undergoing over 2200 thermal cycles in accordance with some embodiments of the present invention.

FIG. 14 provides a SEM image of a cross-section of an interconnected daisy chain after over 2000 thermal cycles along with an inset of an interconnection between a copper bump and a copper substrate pad in accordance with some embodiments of the present invention.

FIG. 15 graphically depicts individual daisy chain resistance values during a thermal cycling test of interconnect assemblies undergoing over 1825 thermal cycles in accordance with some embodiments of the present invention.

FIG. 16(a) provides a SEM image of a cross-section of a failed portion of a daisy chain after about 1995 thermal cycles in accordance with some embodiments of the present invention.

FIG. 16(b) provides a SEM image of the interface of a copper bump and a copper substrate pad for the interconnect noted by the circle in FIG. 16(a) in accordance with some embodiments of the present invention.

FIG. 17 graphically depicts individual daisy chain resistance values during a thermal cycling test of interconnect assemblies undergoing about 1180 thermal cycles in accordance with some embodiments of the present invention.

FIG. 18 is a schematic illustration of an interconnect assembly fabrication step wherein the die is disposed in a cavity within the substrate, showing a tool head and non-conductive filler concentration adjusted for surface roughness of the substrate cavity in accordance with some embodiments of the present invention.

FIG. 19 graphically depicts individual daisy chain resistance values during a thermal cycling test of interconnect assemblies undergoing about 955 thermal cycles in accordance with some embodiments of the present invention.

FIG. 20(a) provides a SEM image of a cross-section of a copper bump on a copper pad after an applied load of about 7 kilograms (about 220 MPa) in accordance with some embodiments of the present invention.

FIG. 20(b) provides a SEM image of a cross-section of a copper bump on a copper pad after an applied load of about 9.5 kilograms (about 300 MPa) in accordance with some embodiments of the present invention.

FIG. 21 graphically depicts individual daisy chain resistance values during a thermal cycling test of interconnect assemblies undergoing about 500 thermal cycles in accordance with some embodiments of the present invention.

FIG. 22 shows test vehicle layout showing daisy chains and Kelvin structures for reliability evaluation for 3 mm×3 mm die (left) and 12 mm×12 mm interposer (right) with probing pads in accordance with some embodiments of the present invention.

FIG. 23 shows an assembly process flow of hybrid thermocompression bonding with pre-applied underfill in accordance with some embodiments of the present invention.

FIG. 24 shows SEM pictures of the ion-milled cross-section of a Si test die assembled on an ultra-thin glass interposer with Cu interconnect formed by thermocompression binding with pre-applied underfill: (a) plastically-deformed Cu microbumps on Cu landing pads (b) close-up view of the microbump-to-pad interface showing ENIG finish layers on bump and pad (c) close-up view of the bonded interface showing trapped polymer pockets and (d) close-up view of the bimetal interface with hybrid metallurgical-covalent bonding in accordance with some embodiments of the present invention.

FIG. 25 graphically depicts the evolution of daisy chains resistance from test sample assembled on organic substrate with RXP (left) and BT (right) core during thermal cycling test showing no failure after 2000 cycles in accordance with some embodiments of the present invention.

FIG. 26 shows SEM images of a failed Cu interconnect after 1995 thermal cycles showing failure at the microbump-to-pad interface in accordance with some embodiments of the present invention.

FIG. 27 graphically depicts the evolution of daisy chains resistance from test samples assembled on organic substrates during electromigration with 10⁶ A/cm² (left) and 10⁵ A/cm² (right) in accordance with some embodiments of the present invention.

### DETAILED DESCRIPTION

Referring now to the figures, wherein like reference numerals represent like parts throughout the several views, exemplary embodiments of the present invention will be described in detail. Throughout this description, various components may be identified having specific values or parameters, however, these items are provided as exemplary embodiments. Indeed, the exemplary embodiments do not limit the various aspects and concepts of the present invention as many comparable parameters, sizes, ranges, and/or values may be implemented. The terms “first,” “second,” “primary,” “secondary,” “top,” “bottom,” “distal,” “proximal,” and the like, do not denote any order, quantity, or importance, but rather are used to distinguish one element from another. Further, the terms “a,” “an,” and “the” do not denote a limitation of quantity, but rather denote the presence of “at least one” of the referenced item.

The various embodiments of the present invention relate to improved fine pitch, chip-to-substrate interconnects to create interconnects between a semiconductor and a substrate. Specifically, a non-metallurgical bond is created between a semiconductor and a substrate by deforming the bump and the corresponding substrate pad and optionally utilizing a non-reactive adhesive to strengthen the bond. The methods of manufacture are also described herein.

The bumps used to make the interconnects described herein can be formed from a variety of metals or alloys. When chosen from a metal, the bump can be formed from copper, aluminum, silver, nickel, lead, palladium, and platinum, among others. If the bump is formed from an alloy, it can be a tin-silver, tin-gold, tin-silver-gold, or other like alloy. In exemplary embodiments, however, the bumps are formed from copper owing to its excellent electrical conductivity, mechanical stability, and relatively inexpensive cost. Additionally, because most semiconductor foundries are now equipped with advanced copper electroplating systems, the manufacturing of copper bump interconnects can be easily integrated into the processes, thus keeping the cost of manufacturing copper bump interconnects relatively low.

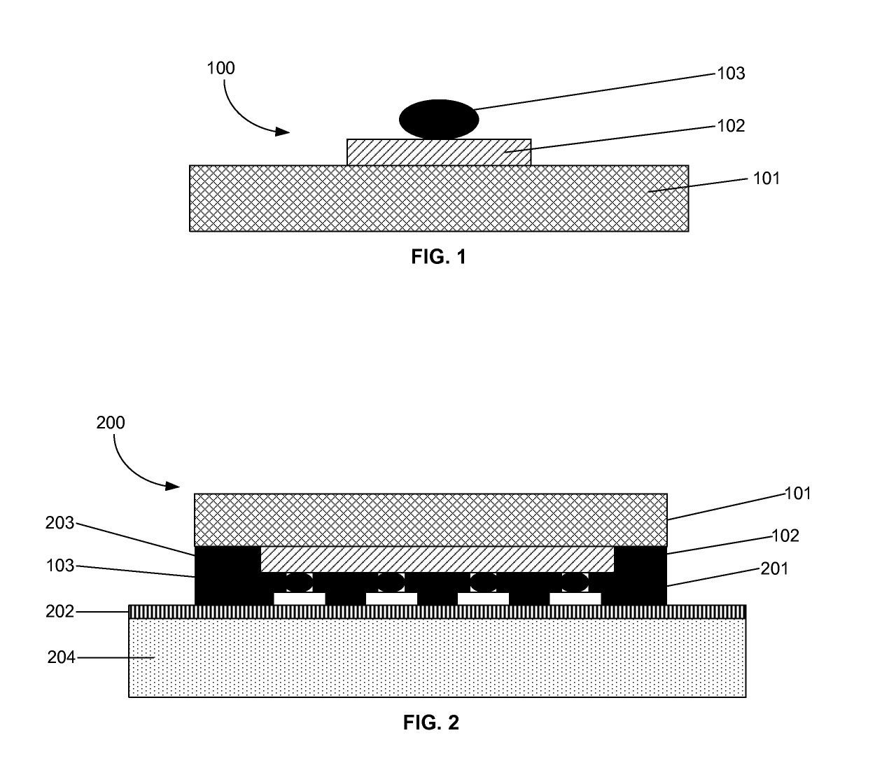

Referring now to FIG. 1, there is shown a semiconductor 101, which, as understood by those skilled in the art to which this disclosure pertains, can also be referred to as a die, an integrated circuit (IC), a wafer, a microcircuit, a microchip, a silicon chip, a semiconductor chip, or a chip. In exemplary embodiments, the semiconductor 101 is made from silicon. In exemplary embodiments, the surface of the silicon semiconductor 101 is oxidized to enhance bonding characteristics. In other exemplary embodiments, glass can be used in place of the silicon semiconductor.

One or more die pads 102 can be disposed on the oxidized or non-oxidized surface of the semiconductor 101. For illustrative convenience, only one die pad 102 is shown in FIG. 1, but it will be understood that the semiconductor 101 is capable of having a plurality of die pads 102 disposed thereon. The die pads 102 can be fabricated from aluminum, copper, titanium, or an alloy or other combination comprising at least one of the foregoing. Many other conductive metals or conductive metal alloys/combinations also can be used to fabricate the die pad 102.

At least one bump 103 can be disposed on each of the die pads 102. As described above, many materials can be used to fabricate the bump 103. The bump 103 also can be coated with a protective finish. It is important, however, that the bump 103 has suitable deformation characteristics to deform at less than or equal to about 300 megaPascals (MPa) of pressure and can withstand temperatures up to about 300 to about 400 degrees Celsius (° C.). The bump 103 can adopt a variety of shapes. In exemplary embodiments, however, the bump 103 is cylindrical in shape, with an oval head. When more than one bump 103 is used, each bump 103 is desirably coplanar with the other bumps 103.

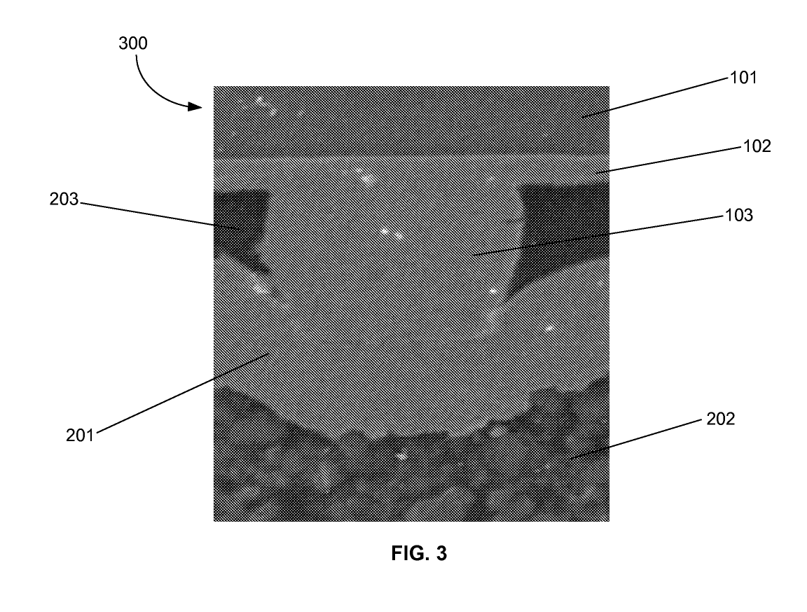

The semiconductor 101, the die pad 102, and the bump 103 generally form the chip assembly 100, which can be “flipped” onto a substrate 204 such that the bump 103 faces the substrate 204. This is illustrated in greater detail in FIG. 2. The “substrate,” as understood by those skilled in the art to which this disclosure pertains, can also be referred to as a printed circuit board (PCB), a printed wiring board (PWB), an etched wiring board, a printed circuit assembly, or a printed circuit board assembly. The substrate 204 can be fabricated from an organic or inorganic material. A dielectric layer 202 can be further disposed on the surface of the substrate 204. The dielectric layer 202 serves to prevent short circuits and provides high-density routing to the chip-to-substrate assembly 200. The dielectric layer 202 can be made of any dielectric material suitable for use in such devices, as would be known to those skilled in the art to which this disclosure pertains. For example, softer dielectric materials (materials with a low Young's Modulus) may allow for more deformation and thus enhance reliability, but even for other dielectric materials which may not deform so readily, the reliability can be obtained by adjusting the pressure such that the pad still deforms without dielectric deformation.

At least one substrate pad or trace 201 can be disposed on the dielectric layer 202. The chip assembly 100 is flipped such that a bump 103 faces the substrate 204 and makes contact with a substrate pad 201. Each substrate pad 201 can have one or more bumps 103 to enhance electrical connectivity. The substrate pads 201 can be formed from a variety of materials; however, it is important that there is sufficient electrical conductivity between the substrate pads 201 and the bumps 103. In exemplary embodiments, the substrate pads 201 are formed from the same material as the bumps 103. The bumps 103 and corresponding substrate pads 201 electrically communicate with each other by contact. A force of pressure is applied to the chip-to-substrate assembly 200, which causes at least the bumps 103 and substrate pads 201 to deform, thereby creating a non-metallurgical contact or connection. Stated another way, the bumps 103 form a pressure contact bond with the substrate pads 201.

If desired, localized metallurgical bonding can be used to enhance the connection between a bump 103 and substrate pad 201. In such cases, the localized metallurgical bonding occurs via an intermediate bonding layer that is disposed between the bump 103 and substrate pad 201 and can be a part of the bump, the pad or the adhesive. That is, when a localized metallurgical bond is implemented, the interaction between the bump 103 and substrate pad 201 is more than a physical pressure contact.

In some embodiments, an adhesive 203 can be used to strengthen the interaction between the bump 103 and substrate pad 201. Before the bump 103 contacts the substrate pad 201, an adhesive 203, having a thickness of about 3 to about 5 micrometers (μm), for example, can be disposed onto the surface of the substrate pad 201. The adhesive 203 can be fabricated from a number of non-conductive films (NCF), for example, but not limited to, polymeric materials. The adhesive 203 can also be fabricated from a number of anisotropically conductive materials. The adhesive 203 material is preferably non-reactive with the other components of the device or assembly. The adhesion properties of the adhesive 203 can be optimized by adding additives, such as adhesion promoters, corrosion inhibitors, and curing agents to reduce the moisture uptake of the adhesive. In preferred embodiments, the adhesive 203 has a storage modulus of about 2 gigaPascals (GPa), a glass transition temperature of about 115° C., and a coefficient of thermal expansion between about 65 and about 70 ppm/° C. The adhesive 203 can be heated to achieve a gel-like structure, which allows the bump 103 to pierce through it and make an electrical connection with the substrate pad 201.

Together, the die pad 102, the bump 103, and the substrate pad 201 make up the interconnect. The height of the interconnect can vary. In exemplary embodiments, however, the height of the interconnect is about 20 μm. The interconnect is adapted to put at least a portion of the semiconductor 101 and at least a portion of the substrate 204 in electrical communication with each other.

A method of manufacturing the chip-to-substrate assembly 200 can generally include fabricating the semiconductor 101, fabricating the substrate 204, and interconnecting the two with a bump 103 such that they are in electrical communication with each other. Semiconductor and substrate fabrications processes are well-known to those skilled in the art, and are therefore not described in detail herein. In some embodiments, the semiconductor is fabricated using silicon chips assembled on glass substrates. The glass substrate enables visual inspection of the assembled chip from the backside, such that high alignment accuracy can be achieved for chips assembled at 30 μm pitch. In other embodiments, the surface of the semiconductor 101 is oxidized. One or more die pads 102 can be subsequently disposed on the oxidized or non-oxidized surface of the semiconductor 101, and one or more bumps 103 can then be disposed on the surface of the one or more die pads 102. In various embodiments, the bumps 103 are made from copper and are substantially coplanar. Coplanarity of the bumps 103 can be achieved using a copper plating process. The die pads 102 and the bumps 103 can be manufactured in such a way that their total height is approximately 13.1 μm with a standard deviation of 0.45 μm.

Before, after, or contemporaneous with assembly of the semiconductor 101, die pads 102, and bumps 103, the substrate 204 can be prepared. In some embodiments, a dielectric layer 202 can serve as the upper surface of the substrate 204. In such cases, substrate pads 201 can be disposed on the surface of the dielectric layer 202. When a dielectric layer 202 is not used as the upper surface of the substrate 204, the substrate pads 201 can be disposed directly on the upper surface of the substrate 204 itself. A thin layer of heated adhesive 203 can be disposed on the substrate pads 201. The chip assembly 100, comprising the semiconductor 101, die pads 102, and bumps 103, can be subsequently “flipped” onto the substrate 204 such that the bump 103 pierces through the adhesive 203 and makes contact with a corresponding substrate pad 201. A pressure of approximately 300 MPa can be applied to the resultant chip-to-substrate assembly 200, causing at least the bumps 103 and the substrate pads 201 to substantially deform. This deformation creates a non-metallurgical, pressure contact bond between the semiconductor 103 and the substrate 204. Other components of the chip-to-substrate assembly 200 also can be deformed under the applied pressure. For example, in some cases, the dielectric layer 202 can at least partially deform from this pressure. The pressure contact bond causes the adhesive 203 to disperse and fill the void space between the semiconductor 101 and the substrate 204, therefore enhancing the bond therebetween. If desired, the adhesive 203 can be subsequently cured.

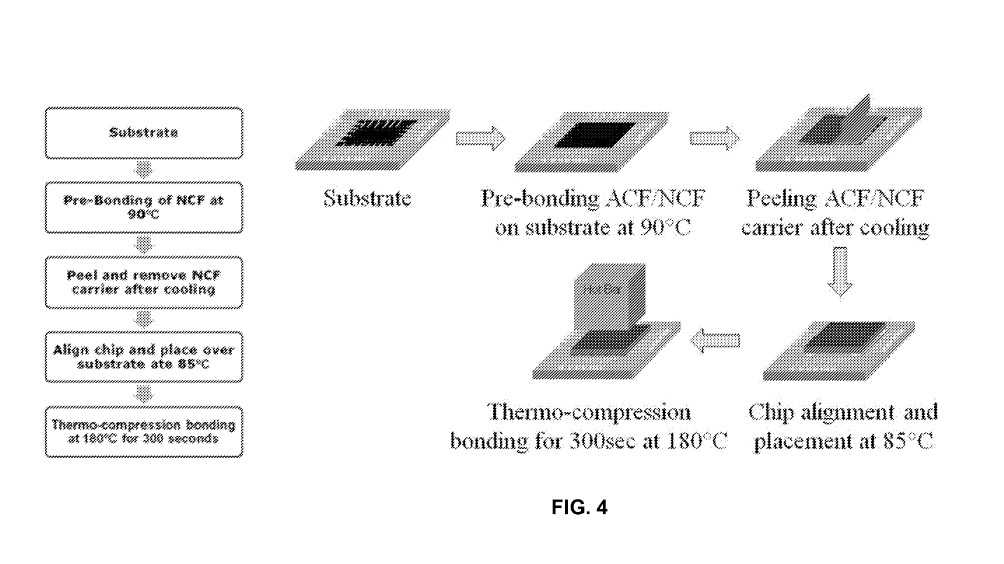

An exemplary schematic process flow for assembly of an interconnect is illustrated in FIG. 4. In these embodiments, the chip-to-substrate assembly 200 is manufactured using a FINETECH Fineplacer© Lambda assembly tool to assist with alignment accuracy (e.g., to an accuracy of about ±1 μm). Tilt of the die while placement on the substrate can be addressed by using a tool head with a gimble, which allows for both preleveling and automatic leveling during assembly. The assembly process for chips bonded on the surface of an organic substrate and/or within a cavity of an organic substrate would be identical. The organic substrate can be pre-bonded with an NCF at about 90° C. for about 15 seconds, followed by cooling to room temperature and removing an NCF liner. The size of the NCF bonded in the cavity of the organic substrate can be controlled to avoid excessive flow of NCF within the cavity, which can lead to an overflow over the cavity wall. The semiconductor or die can then be aligned to the substrate and disposed on it after pre-heating it to about 85° C. to reduce the viscosity of the NCF. Finally the die and the substrate can be subjected to a predetermined load/pressure at about 180° C. for about 30 seconds. The applied load for a 3 millimeter (mm)×3 mm die size is about 21 Newtons (N), which translates to a contact pressure of about 300 MPa on the surface of the bumps. The applied load for a 7 mm×7 mm die size is calculated based on the effective cross-section of all the bumps so that the contact pressure is still approximately 300 MPa.

In some embodiments, the present invention can be a hybrid interconnect assembly. In these embodiments, the bonding mechanism between the bumps and/or landing pads can be hybrid chemical-metallurgical bonding.

Some embodiments of the present invention can be a hybrid interconnect assembly that can comprise a semiconductor, an electrically conductive die pad, a substrate, an electrically conductive substrate pad and a polymer layer. In an embodiment, the die pad can be disposed on at least a portion of a surface of the semiconductor and the substrate pad can be disposed on at least a portion of a surface of the substrate. The polymer layer can be disposed between a surface of the die pad and a surface of the substrate pad. In an embodiment, at least a portion of the surface of the die pad can be metallically bonded to at least a portion of the surface of the substrate pad. In an embodiment, at least a portion of the die pad can be chemically bonded to at least a portion of the polymer layer such that the die pad can be in communication with the substrate pad through the polymer layer. In an embodiment, at least a portion of the substrate pad can be chemically bonded to at least a portion of the polymer layer such that the substrate bad can be in communication with the die pad through the polymer layer. In an embodiment, at least a portion of the surface of the die pad can be chemically bonded to at least a portion of the surface of the substrate pad.

Some embodiments of the present invention can be a hybrid interconnect assembly that can comprise a semiconductor, an electrically conductive die pad, an electrically conducting bump disposed on at least a portion of the die pad or on at least a portion of the substrate pad, a substrate, an electrically conducting substrate pad and a polymer layer. The die pad can be disposed on at least a portion of a surface of the semiconductor and the substrate pad can be disposed on at least a portion of the surface of the substrate. The polymer layer can be disposed between a surface of the die pad and a surface of the substrate pad. In an embodiment, at least a portion of the surface of the bump can be metallically bonded to at least a portion of the surface of the substrate pad and at least a portion of the surface of the bump can be chemically bonded to at least a portion of the surface of the polymer layer such that the bump can be in communication with the substrate pad through the polymer layer. In an embodiment, at least a portion of the surface of the bump can be metallically bonded to at least a portion of the surface of the die pad and at least a portion of the surface of the bump can be chemically bonded to at least a portion of the surface of the polymer layer such that the bump can be in communication with the die pad through the polymer layer. In an embodiment, at least a portion of the surface of the bump can be chemically bonded to at least a portion of one or both of the die pad and the substrate pad.

Metallic or metallurgical bonding can be defined herein as local bonding across two metal interfaces. Chemical bonding can be defined herein as local covalent bonding across a metal and polymer interface. One of ordinary skill in the art to whom this disclosure pertains would understand that the bond strength will depend on the types of metal and polymer used in the interface.

In some embodiments, the surfaces of the interconnections can be non-planar and can comprise one or more defects. The defects can include, but are not limited to pits, holes, pores, surface roughness and the like. The defects can cause portions of the surface of the die pad, the substrate pad and/or the bump to be non-planar. In some embodiments, at least a portion of the surface of the substrate pad can be non-planar and can comprise one or more defects. The substrate pad can have a thickness from about 1 micrometer to about 100 micrometers. In an embodiment, the substrate pad can have a thickness from about 1 micrometer to about 60 micrometers. In another embodiment, the substrate pad can have a thickness from about 1 micrometer to about 30 micrometers. In some embodiments, the substrate pad can have a thickness from about 1 micrometer to about 20 micrometers. In an embodiment, the substrate pad can have a thickness of about 5-10 micrometers.

In some embodiments, at least a portion of the surface of the die pad can be non-planar and can comprise one or more defects. One or more die pads can be disposed on the surface of the semiconductor. The die pads can be fabricated from conductive metals including, but not limited to, aluminum, copper, titanium, or an alloy or other combination comprising at least one of the foregoing. Many other conductive metals or conductive metal alloys/combinations also can be used to fabricate the die pad. The die pad can have a thickness from about 1 micrometer to about 100 micrometers. In an embodiment, the die pad can have a thickness from about 1 micrometer to about 60 micrometers. In another embodiment, the die pad can have a thickness from about 1 micrometer to about 30 micrometers. In some embodiments, the die pad can have a thickness from about 1 micrometer to about 20 micrometers. In some embodiments, the die pad can have a thickness from about 1 micrometer to about 10 micrometers.

At least one bump can be disposed on each of the die pads. In some embodiments, the surface of the bump can be non-planar and can comprise one or more defects. The bump can have suitable deformation characteristics to deform at less than or equal to about 400 megaPascals (MPa) of pressure and can withstand operating temperatures up to about 300 to about 400 degrees Celsius (° C.). It is advantageous for the structure to deform at less than or equal to about 400 MPa to prevent degradation of the interconnections associated with high processing pressures. In some embodiments, when more than one bump is present, each bump can be coplanar with the other bumps. In some embodiments, when more than one bump is present, the bump height can vary from about 0.1 micrometers to about 5 micrometers. It is possible for the substrate, the substrate pad, and/or the die pad to warp during processing. Thus, the bumps can be configured to deform by about 0.1 microns to about 10 microns to accommodate the warpage in the die pad, the substrate pad, and non-planarities in the bump, die pad and/or substrate pad surfaces. In some embodiments, the final assembled die-to-substrate height can vary by about 0.1 microns to about 10 microns to accommodate for the warpage.

A bump can adopt a variety of shapes. In some embodiments, a bump can be cylindrical in shape, with an oval head. Additionally, in some embodiments, a plurality of smaller bumps can be disposed on a larger bump which can facilitate deformation and the hybrid metallic/chemical bonding. In an embodiment, the top of the bump can have a smaller diameter than the bottom of the bump. This can lead to easier deformation of the bump during thermocompression bonding.

As described above, many materials can be used to fabricate the bump and pads. These materials include electrically conducting metals. In some embodiments, the bumps are formed from copper owing to its excellent electrical and thermal conductivities, mechanical stability, and relatively inexpensive cost. However, it is well known in the art that copper and other electrically conducting materials used to fabricate the bumps and pads are sensitive to oxidation. While these metals can have compelling physical properties for fine-pitch high-performance off-chip interconnections, their inherent tendency to form native oxides at room temperature hinder their manufacturability. To overcome the problem of oxide formation on the bump or pads, in some embodiments, the bumps or pads can be coated with a protective finish.

The protective finish can comprise any finish known in the art to protect metals from forming native oxides at room temperature. For example, in one embodiment, the bumps and pads can be protected from oxidation with an electroless nickel immersion gold (ENIG) nickel-gold finish. In some embodiments, the surface finish can comprise palladium, tin, silver, platinum, or mixtures or alloys thereof. The thickness of the surface finish can vary from about 0.1 to about 5 microns. The thickness of the surface finish can be optimized to allow easier deformation and localized metallurgical bonding. In some embodiments, the surface finish can comprise about 200-500 nm of electroless palladium and about 100 nm of immersion gold.

The polymer layer can be an organic layer that can serve to fill in defects on the surface of the die pad, substrate pad, and/or bump. In an embodiment, the polymer layer can comprise a non-conducting film (NCF). The polymer layer can comprise a pre-applied adhesive. In another embodiment, the polymer layer can comprise a no-flow underfill. The polymer layer can also comprise a no-flow underfill, non-conductive adhesive (NCA), an anisotropically conductive film or adhesive (ACF or ACA), a non-conductive paste (NCP), or any non-conductive or anisotropically conductive polymer-based material like epoxy-based molding compounds can also be used with acceptable curing and material properties. One of ordinary skill in the art to whom this disclosure pertains would appreciate the types of polymer layers that could be used to compensate for surface defects and non-planarities in the surfaces.

The polymer layer can be applied prior to assembly and can melt to form a low-viscosity liquid below the bonding temperature, and subsequently cure around the bonding temperature. In some embodiments, the polymer layer can melt and squeeze out from the metal surfaces below the bonding temperatures while still retaining certain residues between the metal contacts. The polymer layer can subsequently cure and form a strong chemical bond between the metal surfaces. The metal surfaces can include the die pad, the substrate pad, or a bump disposed on at least a portion of the die pad. The entrapped polymer pockets can also form a chemical bond between a bump and a pad in areas where plastic deformation may not be enough to initiate a metallurgical bond between the metal surfaces. The entrapped polymer can offset the non-planarities and roughness of bumps and the pads, as well as substrate pad and die pad warpage. The chemical bond, enabled by the liquid polymer, can be used in a hybrid bond with localized metallurgical bonding between two metal surfaces. The chemical bond can occur between the surface of the die pad and the polymer such that the die pad and the substrate pad are in communication through the polymer. In an embodiment, the chemical bond can occur between the surface of the bump and polymer such that the bump is in communication with the die pad and/or the substrate pad through the polymer layer.

The thermocompression can create adequate deformation of the bumps and pads such that they are in intimate contact at local regions. Under high load, the local contacts can undergo a degree of metallurgical interaction, thus creating bonding that can be at least in part metallurgical bonding. As described above, during the thermocompression bonding, excess polymer can be pushed out and cause the metal surfaces to come into contact with each other, facilitating the localized metallurgical bonding.

The metallic or metallurgical bond of the present invention can be facilitated by the surface finish that prevents oxidation. The metal interface can also undergo interdiffusion and enhanced metallurgical bonding during subsequent thermal and electrical treatment. The resistance of the interconnection can drop during electromigration tests, which can indicate that there is some amount of metallurgical interdiffusion and enhancement in metallurgical bonding.

The hybrid metallurgical/chemical bonding of the present invention can be formed by thermocompression bonding. One advantage of the present invention is that the thermocompression bonding conditions, such as lower bonding temperatures and pressures, can allow an increase in the throughput and can lower the manufacturing costs of the interconnections. Furthermore, the lower bonding pressure of the present invention can lead to an increase in yield and a decrease in degradation of the interconnects while still offsetting the non-planarity of the bumps and wafer and substrate warpage.

In some embodiments, the thermocompression bonding can be performed from about 100° C. to about 350° C. In some embodiments, the thermocompression bonding can be performed from about 100° C. to about 300° C. In some embodiments, the thermocompression bonding can be performed from about 100° C. to about 200° C. In some embodiments, the thermocompression bonding can be performed from about 150° C. to about 200° C. In an embodiment, the thermocompression bonding can be performed at about 200° C.

In an embodiment, the thermocompression bonding can be performed from about 100 MPa to about 400 MPa. In some embodiments, the thermocompression bonding can be performed from about 150 MPa to about 300 MPa. In another embodiment, the thermocompression bonding can be performed from about 150 MPa to about 250 MPa. In some embodiments, the thermocompression bonding can be performed at about 200 MPa.

An embodiment of the present invention can be a method of making a hybrid interconnect assembly. The method can comprise providing a semiconductor that comprises an electrically conducting die pad disposed on at least a portion of the surface of the semiconductor and providing a substrate that comprises an electrically conducting substrate pad disposed on at least a portion of a surface of the substrate. At least a portion of the die pad and at least a portion of the substrate pad can have non-planar surfaces, wherein the non-planar surface can comprise at least one defect.

The method can further comprise disposing a polymer layer on the non-planar surface of the substrate pad, aligning and positioning the non-planar surface of the electrically conducting die pad adjacent to or on top of the non-planar surface of the electrically conducting substrate pad, and deforming at least apportion of the die pad and at least a portion of the substrate pad to form at least one of a chemical bond and a metallurgical bond therebetween. The polymer layer can also be disposed on the surface of the semiconductor, the surface of the substrate, the surface of the substrate pad, and/or the surface of the die pad. The chemical bond can occur between at least a portion of the polymer layer and one or more of the surfaces of the die pad and the substrate pad. The metallic bond can occur directly between at least a portion of the surface of the die pad and at least a portion of the surface of the substrate pad.

In an embodiment, the method can further comprise disposing a bump on at least a portion of the die pad or on at least a portion of the substrate pad, wherein the bump is formed from an electrically conducting material, e.g., copper. In an embodiment, the method can further comprise heating the interconnect assembly to a temperature sufficient to melt the polymer, e.g., from about 50° C. to about 150° C. In some embodiments, the chemical bond can occur between at least a portion of the polymer layer and at least a portion of the surface of the bump. In some embodiments, the metallic bond can occur directly between at least a portion of the surface of the substrate pad and at least a portion of the surface of the bump.

The deformation can cause at least a portion of the polymer layer to fill in at least a portion of the at least one defect on the non-planar surfaces of the die pad and the substrate pad. The deforming can also cause at least a portion of the polymer layer to fill in at least a portion of the at least one defect on the non-planar surface of the bump. The deforming can be a plastic deformation. The deforming can comprise applying a pressure of at least 1 MPa to at least 400 MPa.

In an embodiment, the method can further comprise applying a protective finish to one or both of the substrate pad and the die pad. The method can also comprise applying a protective finish to the bump. The protective finish can comprise numerous finishes known in the art to prevent oxidation of at least a portion of the surfaces of the die pad, substrate pad and/or bump. The finishes can include ENIG nickel-gold finish, ENEPIG, EPAG, or combinations or allows of the same materials, and the like. The protective finish can prevent oxidation of at least a portion of the surfaces of the die pad, substrate pad, and bump.

The hybrid interconnection structure and process disclosed herein can offer an advantageous manufacturable process for a broad range of applications with die-to-wafer, die-to-interposer and die-to-package off-chip interconnections. The bumps and pads are protected from oxidation with a protective finish. The excellent malleability and ductile properties of the protective thin film allows for thermocompression bonding at low temperature, for example, below 200° C., with reasonable pressures. Hybrid bonding using a polymer layer, e.g., pre-applied adhesives (NCFs or ACFs) or no-flow underfills, is disclosed herein to enhance the bonding strength and reliability of the formed metallurgical bond. The metal-polymer hybrid bonding can enable the formation of a reliable metallurgical-covalent bond at lower temperature without polymer voiding. Furthermore, the structures and processes disclosed herein do not require surface preparation. Surface preparation can include diamond bit cutting, chemical-mechanical polishing, planarization, surface activation, plasma activation, and the like. Assembly of the structures in ambient air is possible; no vacuum or specific atmosphere is required (e.g., formic acid, forming gas or inert gas). Additionally, the structures and processes disclosed herein allow for processing at lower temperatures coupled with lower pressures and shorter processing times.

### EXAMPLES

In the following examples, various interconnect assemblies were fabricated. The various interconnect designs were fabricated to systematically study the reliability of the interconnections between different die sizes and thicknesses. Performance of the interconnections were also evaluated by embedding the dies in certain organic substrates. That is, flip-chip dies having different thicknesses were interconnected with organic substrates, which either had no cavity or a cavity on the surface.

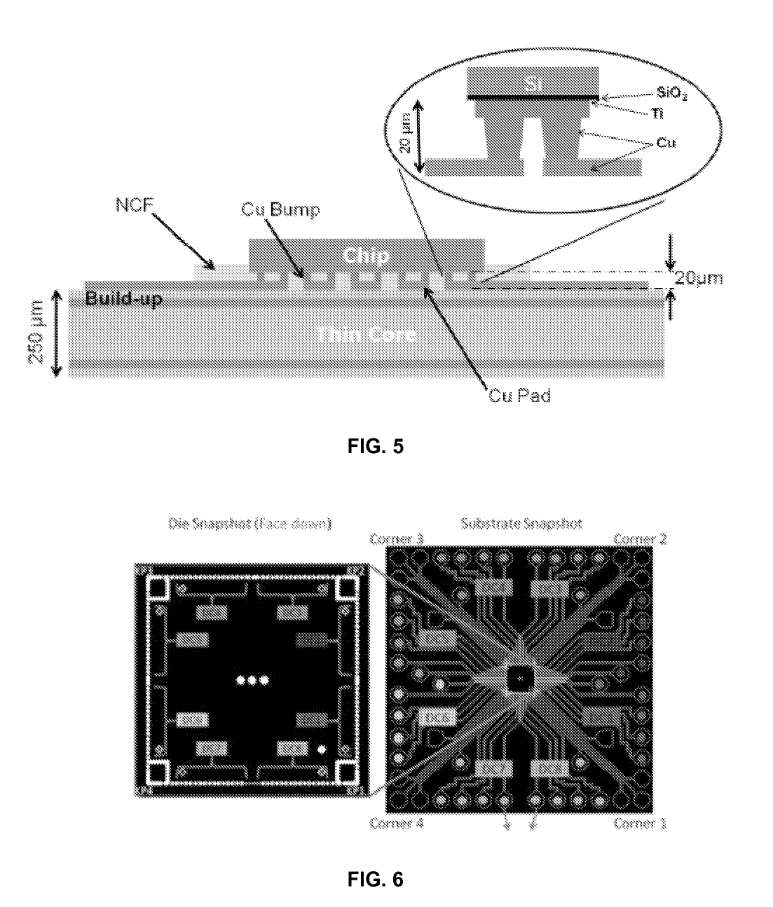

For each of Examples 1-5, the general structure of the interconnect assembly is shown in FIG. 5. In general, the dies were fabricated using a standard semi-additive process (SAP). A die pad layer, having a thickness of about 1 to about 2 μm, was made by electroplating copper over a titanium layer of about 400 Angstrom (Å) thickness. Copper bumps about 12 μm in height were then patterned and electroplated on the die pads. The copper bumps were given a surface finish with nickel and gold using electroless nickel and immersion gold (ENIG) techniques. Copper bumps were fabricated on about 550 μm thick wafers out of which some wafers were thinned down to about 55 μm thickness. In some cases, as will be described below, the about 55 μm thick dies were used to establish the handling and assembly process of such dies prior to embedding them inside a cavity.

The substrates were fabricated using an organic, ultra-high wiring density build-up substrate developed for achieving chip-to-substrate interconnections having a pitch of about 30 μm. This organic substrate comprised a low-loss thin core laminate and low dielectric constant/low-loss build-up dielectric. The pads and traces on the substrate were also given a surface finish using ENIG techniques.

### Example 1

### Design and Fabrication of a Chip-to-Substrate Interconnect Assembly

In this example, the device, which is referred to as “TV1” for convenience, was designed to extract single bump resistance and daisy chain resistance data. This device was designed for 3 mm×3 mm dies and the interconnect layout was peripheral with 360 bumps around the die. The design was comprised of 4 Kelvin test structures and 8 daisy chains with 32 bumps each. FIG. 6 shows the position of Kelvin test structures (KP) and daisy chains (DC) in the die and substrate design. The die design also included fiducials for both alignment and orientation.

The substrate was designed for probing every eight bumps in the daisy chain. The size of the substrate was about 25 mm×about 25 mm and was fabricated without a cavity on the surface. Sixteen probe pads, four on each corner were dedicated to four probe measurement and forty probe pads, ten on each side were designed for daisy chain measurements as shown in FIG. 6.

### Example 2

### Design and Fabrication of a Chip-to-Substrate Interconnect Assembly

In this example, the device, which is referred to as “TV2” for convenience, was designed to test the reliability of the interconnect after completely embedding a thin die in the organic substrate. The design for TV2 was done for about 3 mm×about 3 mm dies having 216 peripheral bumps. As the physical tolerances for this test vehicle were more stringent as compared to TV1, the pitch was relaxed to about 50 μm. The design included 4 Kelvin test structures and 3 full daisy chains and 2 half daisy chains as shown in the design snapshot of the substrate in FIG. 7.

The substrate was designed for probing individual daisy chains. The size of the substrate was about 12 mm×about 12 mm and was fabricated with a cavity on the surface of the substrate. The clearance between the cavity wall and die edge was about 400 μm. The cavity size was determined by considering chip size as well as various tolerances, such as chip size tolerances, cavity process tolerances and chip placement tolerances during assembly. FIG. 7 shows the design of the substrate with the edges of the cavity wall near the pads.

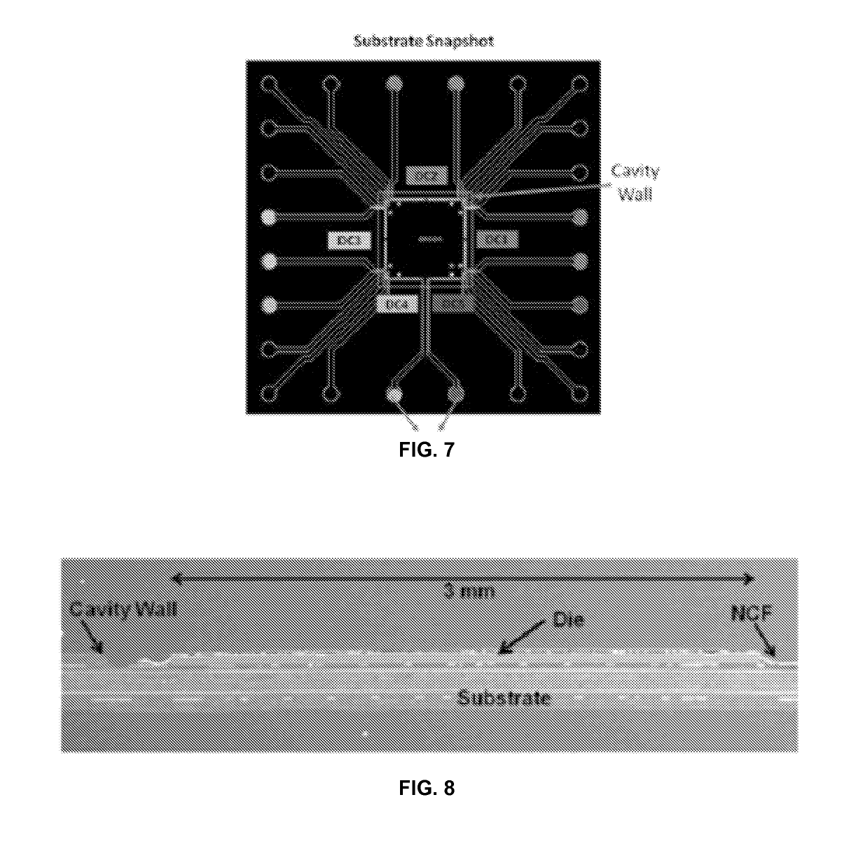

For creating a cavity for embedding the die, three different options were explored, namely: photolithography, plasma etching, and laser drilling. For the plasma etching sample, cavities were created on the surface of the substrate by laminating an about 60 μm thick layer of build-up dielectric on the metallization and drilling out a cavity, slightly larger than the die size, using a CO₂ laser. The thickness of this extra build-up layer was chosen in a way to ensure that the top surface of the die was substantially level with the surface of the build-up. The bottom surface of the cavity was cleaned, prior to assembly, using plasma to remove any debris accumulated from the laser drilling process and ensure a clean copper pad surface. A CF₄/O₂/N₂ plasma was used at about 100° C. for about 5 minutes for complete cleaning. Openings were provided on the about 60 μm thick build-up material to access the probe pads below. The die was assembled inside the cavity such that it was completely contained inside it as shown in the scanning electron microscope (SEM) image of the cross-section of the sample in FIG. 8.

### Example 3

### Design and Fabrication of a Chip-to-Substrate Interconnect Assembly

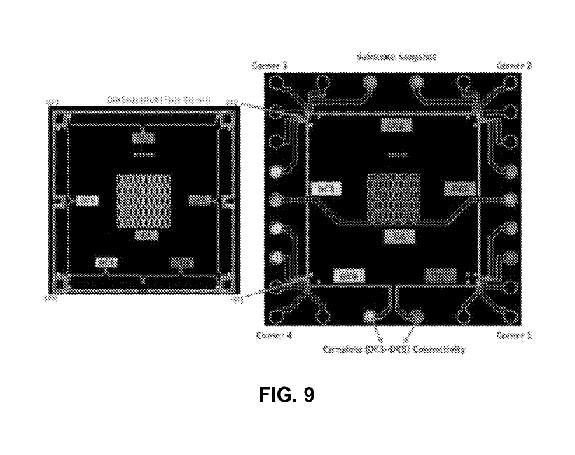

In this example, the device, which is referred to as “TV3” for convenience, was designed for evaluating the reliability of the copper interconnects on a larger die. A die size of about 7 mm×about 7 mm was used. The thickness of the die was about 550 μm. The die design included 537 bumps at about 50 μm pitch arranged around the periphery of the die. A square grid of about 10× about 10 bumps at 200 μm pitch (in both directions) was also incorporated at the center of the die. The design was divided into 3 full daisy chains and 2 half daisy chains along the edge of the die. The substrate was designed to probe individual daisy chains as well as the array of bumps in the center. The size of the substrate was about 12 mm×about 12 mm. The design enabled probing of peripheral daisy chains and the entire array of center bumps from 2 extreme ends as shown in the substrate snapshot in FIG. 9. No cavity was created on the surface of the substrate.

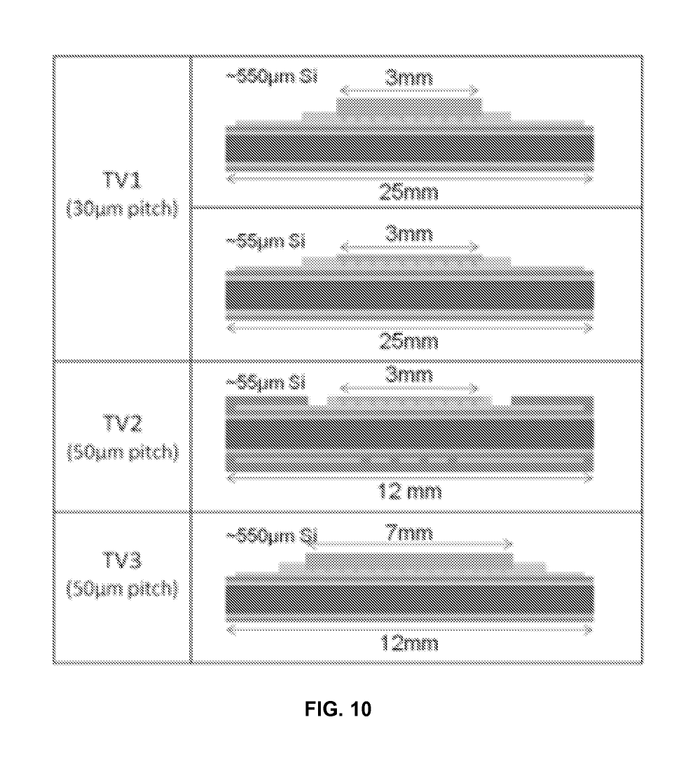

For illustrative convenience, schematic illustrations of the TV1, TV2, and TV3 samples, with relevant dimensions, are shown in FIG. 10.

### Example 4

### Coplanarity Analysis of Copper Bumps

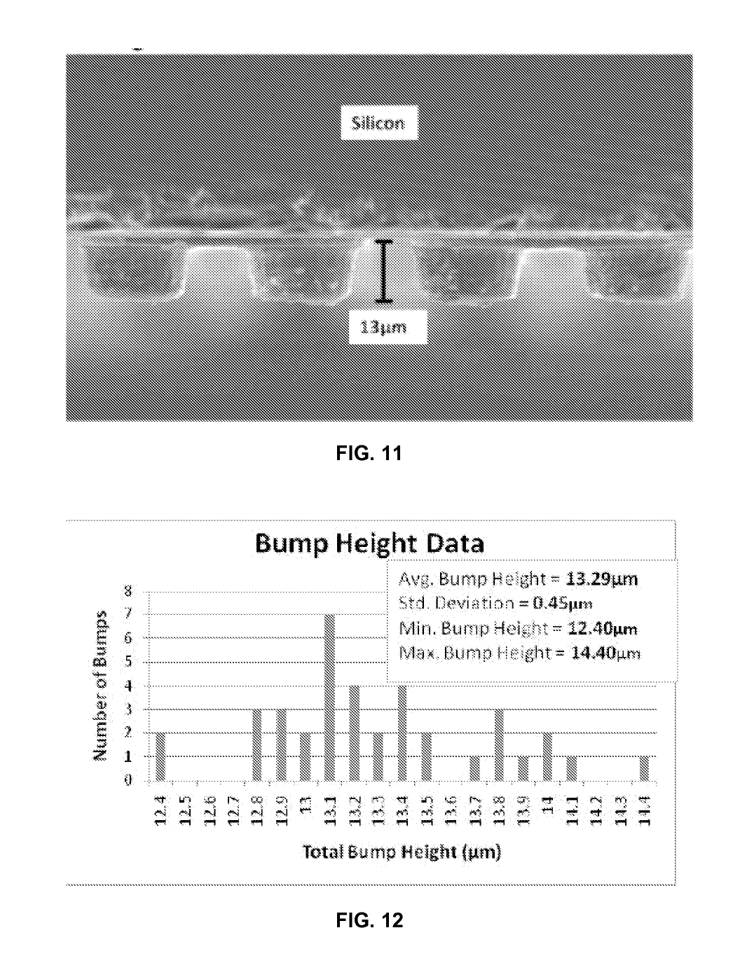

In this example, die bump coplanarity was evaluated using three randomly selected dies from the same wafer and 38 readings were taken at random positions on all four edges of the die. A representative SEM image of coplanar copper bumps on a die is shown in FIG. 11. The results of the analysis are shown in the graph of FIG. 12. The total height (including the pads on the die side) of most of the copper bumps in the study were closely maintained at 13.1 μm with a standard deviation of 0.45 μm. Thus, substantial coplanarity of the copper bumps was achieved.

### Example 5

### Reliability of Interconnect Assemblies

In this example, the reliability of the samples produced in Examples 1-3 were tested. Specifically, samples of TV1, TV2, TV3 were analyzed using the Thermal Cycling Test (TCT) described in JEDEC standard JESD22-A104C (condition B). Assemblies were subjected to a cyclic thermal loading in air from about −55° C. to about 125° C. with a dwell time of about 15 minutes at each extreme temperature. In order to maintain consistency with the standard reliability testing procedure in the industry, all the samples were subjected to a preconditioning (precon) as per joint IPC/JEDEC Standard J-STD-020A before subjecting the samples to any reliability tests. This involved baking the assemblies at about 125° C. for about 24 hours prior to subjecting them to moisture sensitivity level-3 (MSL-3) at about 60° C. and about 60% relative humidity (RH) for about 40 hours followed by 3 times reflow with a peak reflow temperature of about 260° C.

The assemblies were closely monitored using c-mode scanning acoustic microscopy (C-SAM) before and after the preconditioning process for comparison. Individual daisy chain resistance measurements were taken periodically during the thermal cycling tests.

The reliability of TV1 samples will now be discussed. There were two configurations for TV1 as shown in FIG. 10. Specifically, these samples were assembled using both about 550 μm and about 55 μm thick dies on similar organic substrates for testing their performance under TCT. Daisy chain resistance values were recorded after every about 100 cycles. The results of both configurations are discussed in detail below.

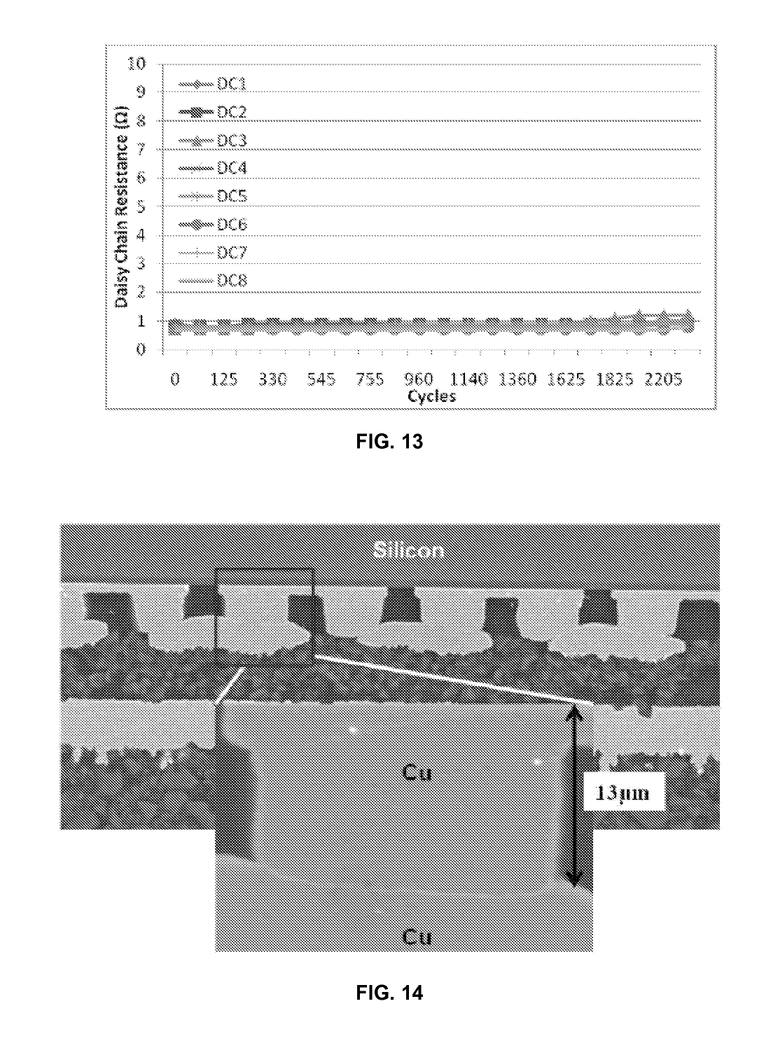

First, reference will be made to the TV1 samples having the about 550 μm thick die. All of these samples showed negligible change in daisy chain resistance values through about 1500 cycles. Beyond this, some samples started exhibiting an increase in daisy chain resistance values at different points during the test. All the samples were thermally cycled to failure to investigate the mode of failure. The failure analysis was performed using SEM for imaging the cross-section of the failed daisy chain. For example, FIG. 13 graphically shows that the daisy chain resistance values changed negligibly until about 1500 cycles, with a marginal increase until about 2300 cycles.

FIG. 14 includes a representative SEM image of a cross-section of a daisy chain illustrating a working copper-to-copper interconnection after over 2000 cycles. The interface of a representative copper bump/copper pad interconnection is shown in the inset of FIG. 14.

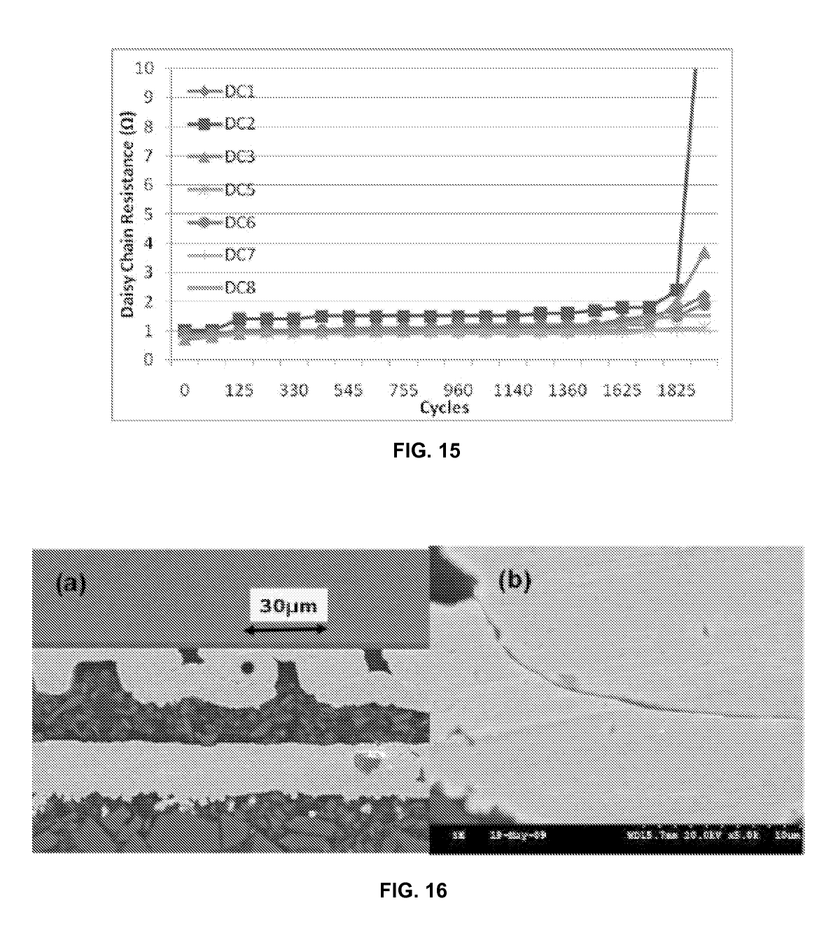

It should be noted that some samples exhibited a significant increase in the daisy chain resistance, indicating an open connection(s) after about 1800 cycles. This is graphically depicted in FIG. 15. These samples were investigated for mode of failure using an SEM. A representative SEM image of a failed daisy chain is shown in FIG. 16(a). The failure of the daisy chain was attributed to the separation of a copper bump from a copper pad, as shown in FIG. 16(b).

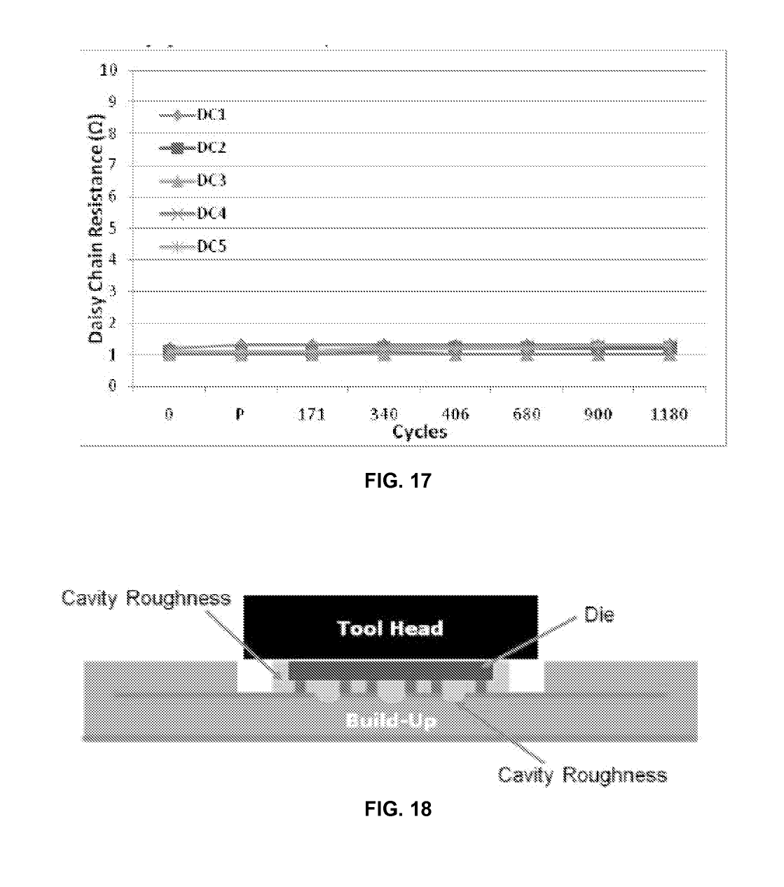

Reference will now be made to the TV1 sample having the about 55 μm thick die. The assemblies with thinned dies also were subjected to more than 1000 cycles of TCT. The results of the TCT are shown graphically in FIG. 17. It should be noted that these results do not include data for the daisy chains that did not electrically connect during assembly due to imperfections in the die or the substrate at the start of TCT. The assembly process for thinned dies ensured that a load of about 300 MPa was applied to the copper bumps without damaging the die itself. The reliability results established a working assembly process for the about 55 μm thick dies.

The reliability of the TV2 samples will now be discussed. The assembly process was challenging for these samples, because the die was completely embedded in a cavity on the surface of the substrate. One key for a highly reliable assembly was to ensure that the applied load on the copper bumps was equivalent to that used earlier for dies assembled on the surface of the substrate. Another issue was to ensure a sufficiently thick NCF to completely fill the gap between the die and substrate. The assembly process was customized by using a proper tool head for placing the die and using a thicker NCF, thus accounting for the roughness created at the base of the cavity due to laser drilling as shown schematically in FIG. 18.

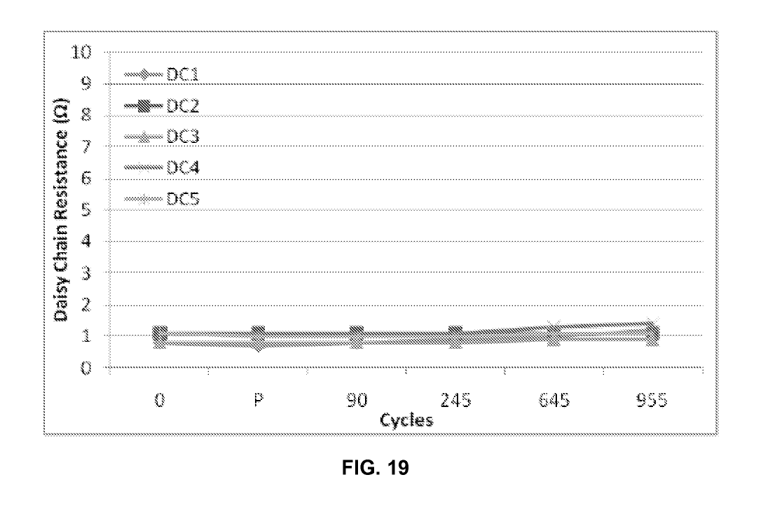

After the process was developed, the samples exhibited stable daisy chain resistance under thermal cycling for about 1000 cycles as shown graphically in FIG. 19. The C-SAM images confirmed a uniform flow of NCF between the die and substrate and no air gaps were observed after the process improvement.

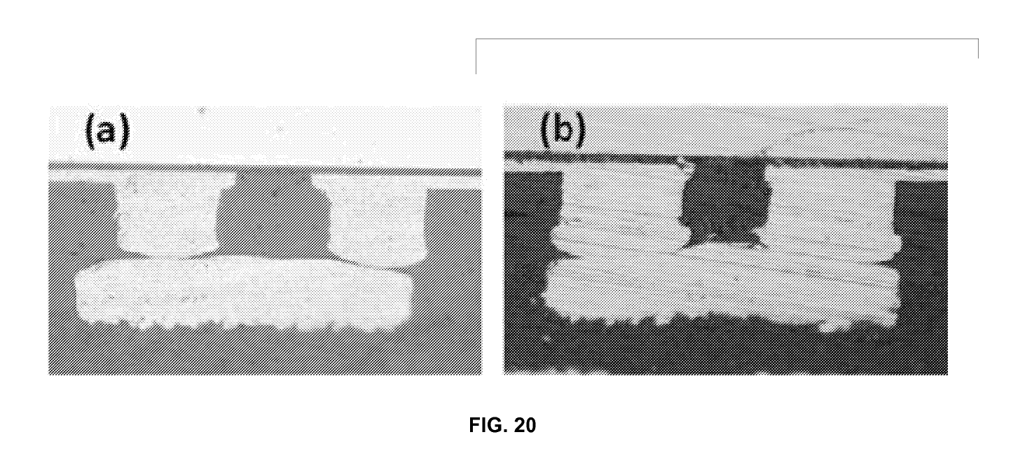

The reliability of the TV3 samples will now be discussed. As mentioned earlier, these samples had greater copper bump to pad contact areas relative to the smaller (i.e., about 3 mm×about 3 mm) dies. As a result, a higher applied load was required to get sufficient deformation of the bump and pad. The appropriate load was calculated considering the total contact surface of the bumps and pads. Greater deformations were seen after increasing the load as shown in the SEM images of FIG. 20. Specifically, the partially interconnected bump and pad in FIG. 20(a) was subjected to a load of about 220 MPa, while the interconnected bump and pad in FIG. 20(b) was subjected to a load of about 300 MPa.

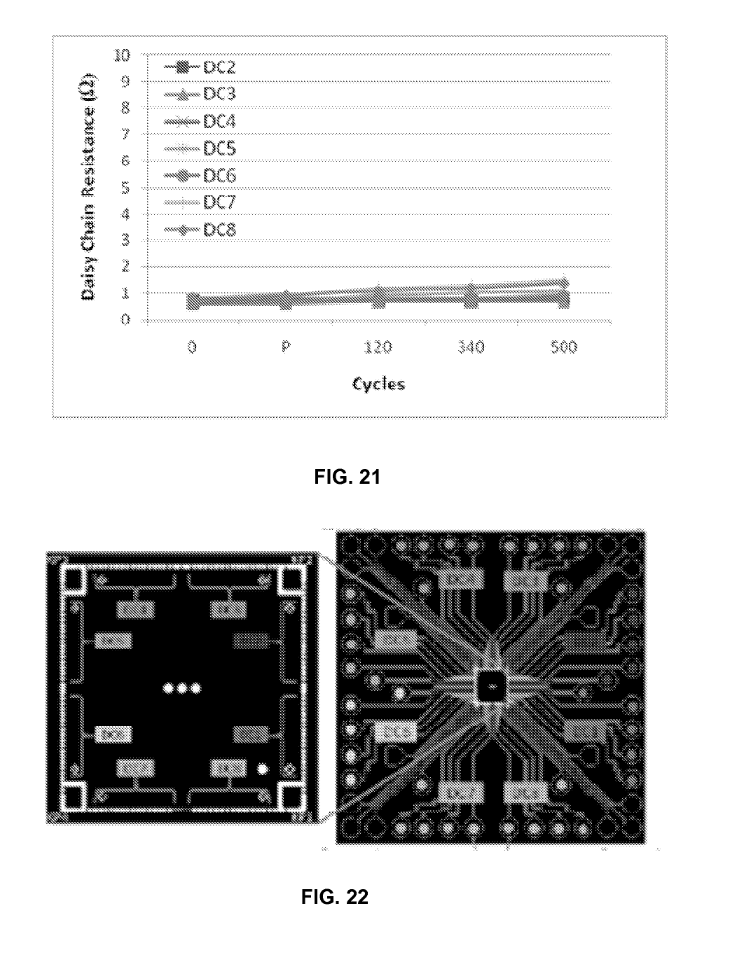

The assemblies with the higher applied loads showed significant improvement in the reliability. As shown graphically in FIG. 21, the daisy chains showed a stable contact resistance through about 500 cycles.

These examples demonstrated the fabrication and effectiveness of the interconnect assemblies of the present invention. This technology enables ultra-fine pitch and low profiles, which in turn enable higher I/O density, low bonding temperatures, reworkability, testability, and ease of integration with existing manufacturing facilities. To summarize, copper bumps on silicon dies were bonded to copper pads on organic substrates using NCF at about 160° C. The dies were assembled both on the surface and within cavities on an organic substrate. The samples were designed to have a pitch of about 30 to about 50 μm to extract single bump resistance, insulation resistance of NCF and daisy chain resistance. TCT results reinforced the excellent reliability of these interconnections. Both thick die and thin die assemblies exhibited excellent results in thermal cycling and maintained stable contact resistance during the test. The assemblies with larger die sizes of about 7 mm×about 7 mm went through more than 500 cycles of thermal cycling. These initial results for large dies indicated that these interconnections can have applicability to larger dies having high I/O counts. Deformation of copper bumps and pads under the applied load resulted in excellent reliability.

### Example 6

### Hybrid Chemical/Metallurgical Bond Interconnections

Test Vehicle Design and Fabrication. A test vehicle with daisy-chain structure was designed to assess the reliability of the Cu interconnects after hybrid metallurgical-covalent bonding, and thus features daisy chain structures. The Si die is 3 mm×3 mm and 55 μm thick, with 360 Cu bumps in a 1-row peripheral configuration at 30 μm pitch. The design includes 4 Kelvin-test structures for corner daisy chains, and 5 edge daisy chains, as illustrated in FIG. 22.

The dies were fabricated from a 400 μm thick wafer using the standard semi-additive process. A 2 μm thick SiO₂ layer was first deposited by Plasma-Therm PECVD, followed by sputtering of a 30 nm Ti-500 nm Cu seed layer. A 2.5 μm Cu dogbone redistribution layer is then laid out on the wafer by electrolytic plating, followed by bumping photolithography and electroplating of the ˜10 μm height Cu bumps. After photoresist strip, ENIG surface finish is applied on the Cu bumps to prevent oxidation. This surface finish consists of 200-500 nm of electroless Ni and ˜100 nm of immersion Au.

Patterned 12 mm×12 mm glass interposers were used to investigate the bonding mechanism, with the specific design for reliability evaluation introduced in FIG. 22 enabling the probing of the individual daisy chains as well as the entire peripheral row. A 6″×6″ 100 μm thick glass panel is first laminated on both sides with a 10 μm thick polymer material. A Cu seed layer is then built by electroless plating on top of the polymer, followed by lithography and Cu electrolytic plating of the ˜10 μm thick race-track traces acting as landing pads on interposer side. After photoresist strip and etching of the Cu seed layer, ENIG surface finish is plated with ˜1 μm Ni and ˜100 nm immersion Au thickness. Organic substrates were also fabricated with new low-loss thin-core laminate and low-dielectric-constant and low-loss build-up dielectric such as BT or RXP to achieve ultra-high density chip-to-substrate interconnections.

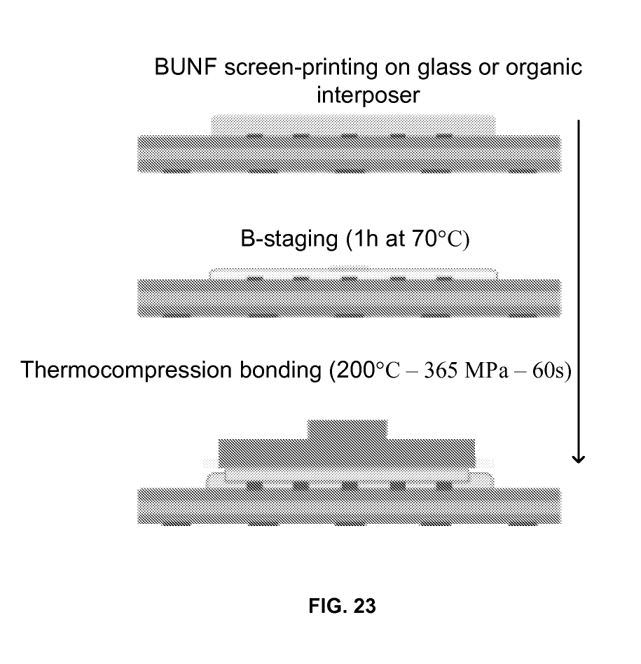

The assembly process was previously established with Si dies on glass interposers and organic packages and is following the process flow detailed in FIG. 23. B-stageable no-flow underfill without fillers is first dispensed on the glass interposer with a fine control of the viscosity and deposited volume, before B-staging at 70° C. for 1 h in air. The Si die was assembled onto the underfill-coated glass interposer with a Finetech Lambda manual flip-chip bonder with a placement accuracy of ±0.5 μm. A gimbal tool head, enabling pre-levelling of the die, was used to prevent any die tilt during assembly. Thermocompression bonding was performed at 200° C., 300 MPa for 60 s, allowing for enough time for the underfill to fully cure.

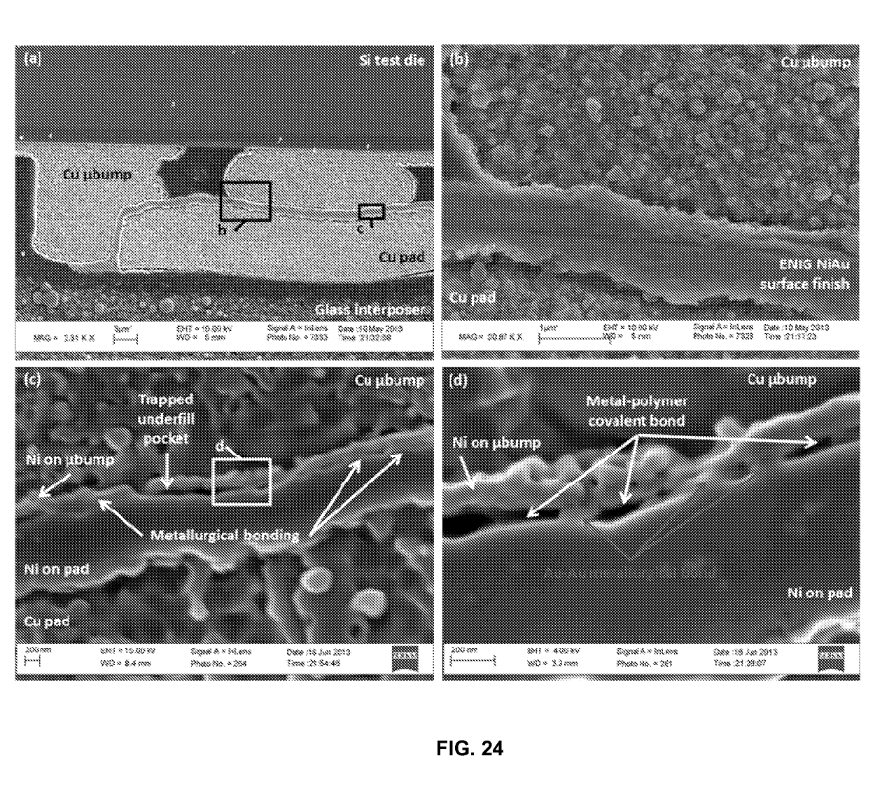

The SEM (scanning electron microscopy) picture in FIG. 24a shows the cross-section of a Si die (top) on a polymer-laminated glass interposer (bottom) with the novel Cu interconnect process after ion milling. The pre-applied underfill fills the gap between die and interposer without any apparent voids. Both Cu bumps and landing pads are plastically deformed, accommodating for more than 3 μm non-coplanarity. FIG. 24 b&c are close-up SEM pictures of the bump-to-pad interface, showing a Cu—Ni—Au—Ni—Cu stack-up. The lack of a distinct interface between the Au bonding layers indicates Au—Au fusion and metallurgical bonding from the ENIG surface finish. Entrapped polymer pockets from the pre-applied underfill form a chemical covalent bond between the bump and pad in areas where plastic deformation was not enough to initiate intimate contact between the 2 surfaces, preventing metallurgical bonding, as shown in FIG. 24d. This hybrid metallurgical-covalent bond originates from the interconnection material, structure and process enabling high local plastic deformation induced by thermocompression of the microbumps and pads.

The 10 μm thick polymer coating on the glass interposer exhibits viscoelastic properties and reaches low viscosity during the initial heating step beyond its glass transition temperature. The pre-applied underfill which contains no fillers changes into a non-conductive liquid at temperatures of 100-110° C. in its pre-cured stage. The excess material is thus squeezed out from the bonding interface, initiating contact between microbump and pads. During assembly, the pressure applied on the die transfers directly to the Cu microbumps in a 300 MPa bonding stress. When the bonding stress exceeds the yield strength of the copper, plastic deformation at the bump-to-pad interface ensues, accounting for most of the surface roughness and non-planarities. The deflection of the Cu landing pads and bumps leads to partial collapse of the bumps. In areas where the metal is not stressed beyond its yield strength due to local non-planarities, pockets of underfill are trapped as could be seen in FIG. 24 c&d.

Local plastic strain brings the thin immersion Au layers into intimate contact, enabling solid-state interdiffusion of the Au atoms. The combination of 3 interdependent factors—pressure to reduce diffusion distances and accelerate material interdiffusion by enhancing dislocation and lattice defect densities at the interfaces, temperature to increase the diffusion rate, and time for interface recrystallization—leads to the formation of the observed Au—Au metallurgical bond. Ni acts as a barrier layer to prevent diffusion of Au into Cu, eliminating the risk of Kirkendall voids formation. The slow interdiffusion rate of Ni and Au ensures that Au—Au self-diffusion is the driving mechanism at the interface. The entrapped polymer forms a chemical covalent bond in the no-contact areas, and assists metallurgical bonding by locally inducing compressive stress in the structure due to shrinkage of the polymer during curing. Due to its fluxing action, it also prohibits oxidation and degradation of Cu interconnects, and enhances the die shear strength.

The bond strength was evaluated by die shear testing of 5 newly assembled samples using a Dage 4000 shear tester. All dies survived the maximum applicable force of 20 kgf, the off-chip interconnection being stronger than the equipment capability. The proposed hybrid Cu interconnect thus passed the MIL-STD-883G standard.

Reliability samples were assembled following the described process flow on organic substrates and subjected to high-temperature storage (HTS), unbiased highly-accelerated stress test (U-HAST), thermal cycling test (TCT) and electro-migration test (EM).

HTS test follows the JEDEC standard JESD22-A103C (condition C). The assemblies were subjected to 175° C. in air for 72 h. The U-HAST was conducted in accordance with the JEDEC standard JESD22-A118 (condition A) consisting in storage of the tested samples at 130° C. and 85% relative humidity (RH) for 96 h. TCT was performed from −55° C. to 125° C. with a dwell time of 15 min at each temperature extreme as recommended by JEDEC standard JESD22-A104C (condition B). All samples were pre-conditioned as per joint IPC/JEDEC Standard J-STD-020A prior to reliability testing: baking at 125° C. for 24 h followed by moisture sensitivity level-3 at 60° C. 60% RH for 40 h, before 3 times reflow with 260° C. peak temperature. The EM test was pursued with 2 different current densities: 10⁴ A/cm² and 10⁵ A/cm² at 130° C.

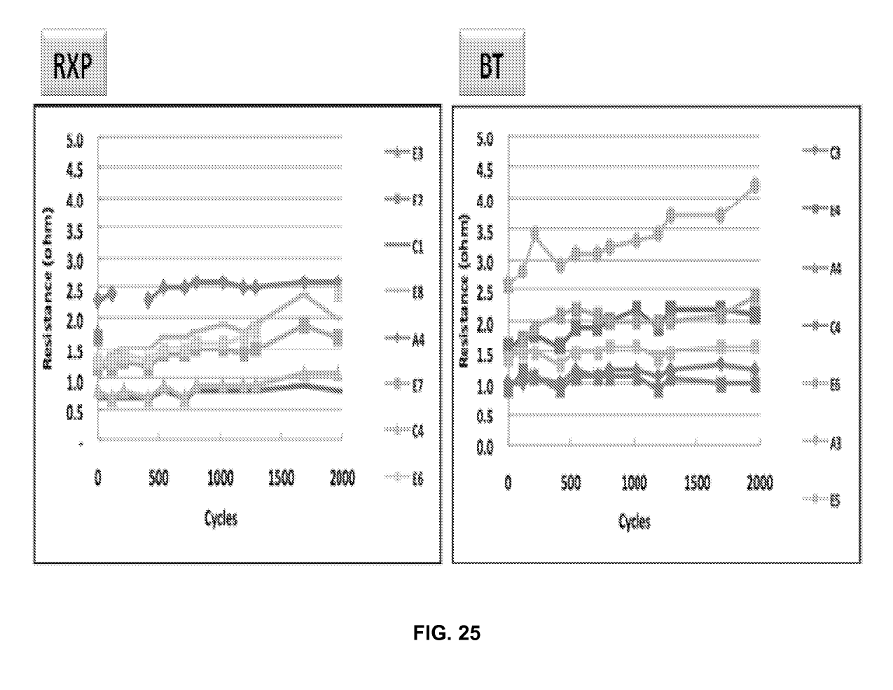

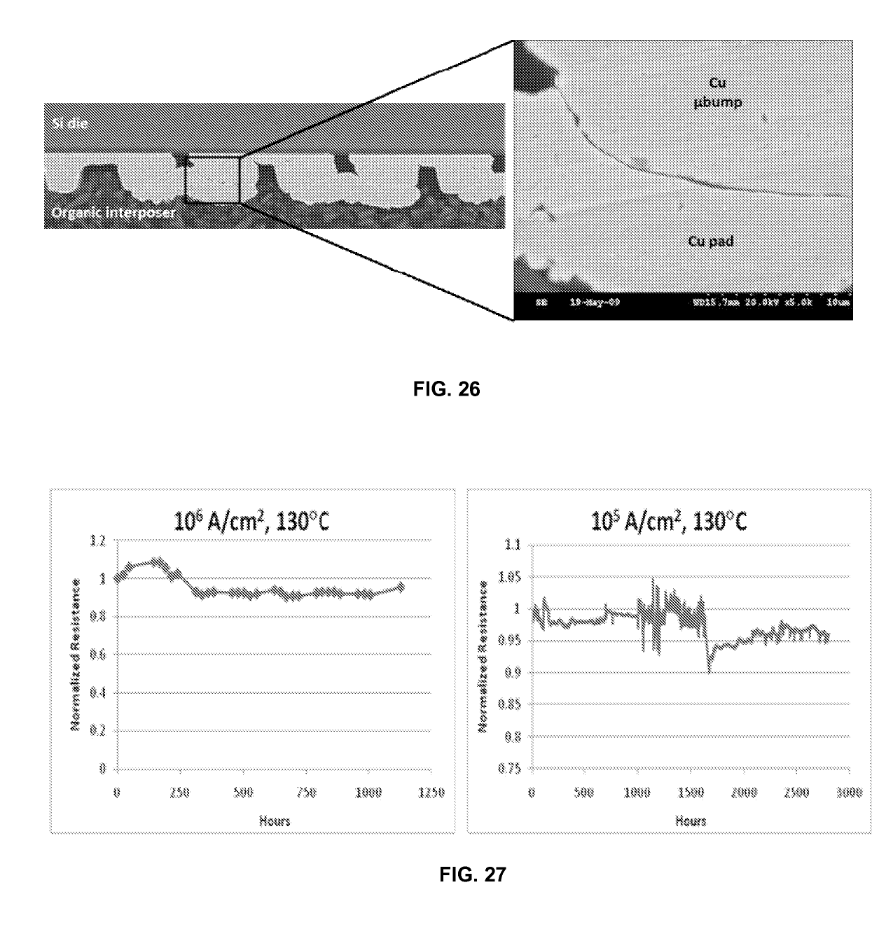

The samples exhibited no failure during HTS test. Moisture-induced hygroscopic swelling has been identified as the primary failure mode for flip-chip assembly with adhesives or polymer-based underfills when subjected to U-HAST. No moisture ingress could be detected in the samples even after 192 h of U-HAST testing. The tested samples also survived >2000 thermal cycles in TCT, as confirmed by the graphs of FIG. 25 showing the monitored daisy chains resistance in test. Failure occurred at the bump-to-pad interface, ensuing from crack propagation within the bonded Au layers as indicated by the SEM picture of a failed interconnect after 1995 thermal cycles shown in FIG. 26. As for EM testing, the assemblies survived ˜800 h without failures at 10⁶A/cm² and >2800 h without failures at 10⁵ A/cm². As observed in FIG. 27, the resistance decreased over time under current and temperature stressing. This drop in resistance indicates ongoing metallic interdiffusion enhancing the pre-existing metallurgical bond.

The embodiments of the present invention are not limited to the particular formulations, process steps, and materials disclosed herein as such formulations, process steps, and materials can vary somewhat. Moreover, the terminology employed herein is used for the purpose of describing exemplary embodiments only and the terminology is not intended to be limiting since the scope of the various embodiments of the present invention will be limited only by the appended claims and equivalents thereof. For example, dimensional, temperature, and pressure parameters can vary depending on the particular materials used.

Therefore, while embodiments of this disclosure have been described in detail with particular reference to exemplary embodiments, those skilled in the art will understand that variations and modifications can be effected within the scope of the disclosure as defined in the appended claims. Accordingly, the scope of the various embodiments of the present invention should not be limited to the above discussed embodiments, and should only be defined by the following claims and all equivalents.

We claim:

1. A hybrid interconnect assembly, comprising:
a semiconductor;
a die pad disposed on at least a portion of a surface of the semiconductor, wherein the die pad is formed from an electrically conducting material;
a substrate;
a substrate pad disposed on at least a portion of a surface of the substrate, wherein the substrate pad is formed from an electrically conducting material; and
a polymer layer disposed between a surface of the die pad and a surface of the substrate pad;
wherein at least a portion of the surface of the die pad is metallurgically bonded to at least a portion of the surface of the substrate pad and at least a portion of the surface of the die pad is chemically bonded to at least a portion of the surface of the substrate pad.

2. The hybrid interconnect assembly of claim 1, further comprising a bump disposed on at least a portion of one of the die pad or the substrate pad, wherein the bump is formed from an electrically conducting material.

3. The hybrid interconnect assembly of claim 1, wherein at least a portion of the surface of one or both of the die pad and substrate pad is non-planar and comprises one or more defects.

4. The hybrid interconnect assembly of claim 3, wherein the polymer layer is configured to fill in at least a portion of the one or more defects in one or both of the die pad and substrate pad.

5. The hybrid interconnect assembly of claim 1, wherein the polymer layer is formed from a non-conductive film.

6. The hybrid interconnect assembly of claim 1, wherein one or both of the die pad and substrate pad is formed from copper.

7. The hybrid interconnect assembly of claim 2, wherein the bump is formed from copper.

8. The hybrid interconnect assembly of claim 1, wherein at least a portion of one or both of the die pad and the substrate pad is deformed to chemically bond to at least a portion of the surface of the polymer layer such that at least a portion of the surface of the die pad is in communication with at least a portion of the surface of the substrate pad through the polymer layer; and.
wherein at least a portion of one or both of the die pad and the substrate pad is deformed to metallurgically bond at least a portion of the surface of the die pad to at least a portion of the surface of the substrate pad.

9. The hybrid interconnect assembly of claim 2, wherein at least a portion of the bump is deformed to chemically bond to at least a portion of the surface of the polymer layer such that at least a portion of the bump is in communication with at least a portion of the surface of one or both of the die pad or the substrate pad through the polymer layer; and
wherein at least a portion of one or both of the die pad and the substrate pad is deformed to metallurgically bond at least a portion of the surface of the die pad to at least a portion of the surface of the substrate pad.

10. The hybrid interconnect assembly of claim 1, wherein the die pad has a thickness of about 1 micrometer to about 10 micrometers.

11. The interconnect assembly of claim 1, wherein the substrate pad has a thickness of about 1 micrometer to about 20 micrometers.

12. The hybrid interconnect assembly of claim 2, wherein one or more of the die pad, the substrate pad and the bump further comprise a protective finish.

13. A method of making a hybrid interconnect assembly, the method comprising:
providing a semiconductor that comprises an electrically conducting die pad disposed on at least a portion of a surface of the semiconductor, at least a portion of the die pad having a non-planar surface, the non-planar surface of the die pad comprising one or more defects;
providing a substrate that comprises an electrically conducting substrate pad disposed on at least a portion of a surface of the substrate, at least a portion of the substrate pad having a non-planar surface, the non-planar surface of the substrate pad comprising one or more defects;
disposing a polymer layer on one or more of the surface of the semiconductor, the surface of the substrate, the surface of the substrate pad, and the surface of the die pad;
positioning the surface of the die pad adjacent to the surface of the electrically conducting substrate pad; and
deforming at least a portion of the die pad and at least a portion of the substrate pad to form at least one of a chemical bond and a metallic bond therebetween.

14. The method of claim 13, further comprising disposing a bump on at least a portion of one of the die pad or the substrate pad, wherein the bump is formed from an electrically conducting material.

15. The method of claim 13, further comprising heating the interconnect assembly to a temperature sufficient to melt the polymer.

16. The method of claim 15, wherein the heating occurs at about 50° C. to about 150° C.

17. The method of claim 13, wherein the deforming causes at least a portion of the polymer layer to fill in at least a portion of the one or more defects on the non-planar surfaces of at least one of the die pad and the substrate pad.

18. The method of claim 14, wherein the deforming causes at least a portion of the polymer layer to fill in at least a portion of the one or more defects on the non-planar surfaces of one or more of the die pad, the substrate pad, and the bump.

19. The method of claim 13, wherein the deforming comprises applying a pressure of at least about 100 to about 400 MPa.

20. The method of claim 13, wherein the chemical bond occurs between at least a portion of the polymer layer and one or more of the surfaces of the die pad and the substrate pad; and
wherein the metallurgical bond occurs directly between at least a portion of the surface of the die pad and at least a portion of the surface of the substrate pad

21. The method of claim 14, wherein the chemical bond occurs between at least a portion of the polymer layer and one or more of the surfaces of the bump, the die pad and the substrate pad; and
wherein the metallurgical bond occurs directly between at least a portion of one or more of the surfaces of the bump, the die pad, and the substrate pad.
